(19) United States
(12) Patent Application Publication
(10) Pub. No.: US 2020/0212022 A1
(43) Pub. Date: Jul. 2, 2020

(54) MICRO LIGHT-EMITTING DIODE DISPLAY FABRICATION AND ASSEMBLY APPARATUS

(71) Applicant: Intel Corporation, Santa Clara, CA (US)

(72) Inventor: Khaled AHMED, Anaheim, CA (US)

(21) Appl. No.: 16/235,831

(22) Filed: Dec. 28, 2018

(51) Int. Cl. H01L 25/16; H01L 27/12; H01L 33/62; H01L 33/44; H01L 33/60; H01L 33/42; H01L 33/24; H01L 33/00; H01L 21/67

(52) U.S. Cl. CPC H01L 25/167; H01L 27/1218; H01L 33/62; H01L 33/44; H01L 33/60; H01L 33/42; H01L 2933/0066; H01L 27/1222; H01L 33/24; H01L 33/0079; H01L 33/007; H01L 21/67144; H01L 27/1225

(57) ABSTRACT

Micro light-emitting diode display fabrication processes and assembly apparatuses are described. In an example, a micro light emitting diode pixel structure includes a backplane including a glass substrate having an insulating layer disposed thereon, and a pixel thin film transistor circuit disposed in and on the insulating layer, the pixel thin film transistor circuit including a gate electrode and a channel. The micro light emitting diode pixel structure also includes a front plane including a metal pad coupled to the pixel thin film transistor circuit of the backplane, a micro light emitting diode device bonded to the metal pad, a spacer adjacent sidewalls of the micro light emitting diode, the spacer including a high refractive index material, and an insulating layer surrounding the spacer.

### TECHNICAL FIELD

Embodiments of the disclosure are in the field of micro-LED displays and, in particular, micro light-emitting diode display fabrication processes and assembly apparatuses.

### BACKGROUND

Displays having micro-scale light-emitting diodes (LEDs) are known as micro-LED, mLED, and μLED. As the name implies, micro-LED displays have arrays of micro-LEDs forming the individual pixel elements.

A pixel may be a minute area of illumination on a display screen, one of many from which an image is composed. In other words, pixels may be small discrete elements that together constitute an image as on a display. These primarily square or rectangular-shaped units may be the smallest item of information in an image. Pixels are normally arranged in a two-dimensional (2D) matrix, and are represented using dots, squares, rectangles, or other shapes. Pixels may be the basic building blocks of a display or digital image and with geometric coordinates.

### BRIEF DESCRIPTION OF THE DRAWINGS

FIG. 1 is a schematic illustration of a micro light emitting diode (LED) display architecture, in accordance with an embodiment of the present disclosure.

FIG. 2 illustrates a cross-sectional view of a schematic of a display bonder apparatus, in accordance with an embodiment of the present disclosure.

FIG. 3 illustrates a schematic view of an infra-red laser ablation module, in accordance with an embodiment of the present disclosure.

FIG. 4 illustrates a schematic of a meta-surface array used to sweep an angular position of a transmitted beam, in accordance with an embodiment of the present disclosure.

FIGS. 5A-5C illustrate cross-sectional views of various operations in a method of assembling a micro LED display, in accordance with an embodiment of the present disclosure.

FIG. 6 illustrates a schematic of an angled view of a meta-atom (cylindrical nanopost) on a dielectric (left), a top view of the meta-surface device composed of meta-atoms on a hexagonal lattice showing geometrical parameters (center), and a cross-sectional view of a meta-surface device (right), in accordance with an embodiment of the present disclosure.

FIG. 7A includes governing equations for transmission mode and reflection mode, in accordance with an embodiment of the present disclosure.

FIG. 7B is a diagram used to deduce the transmission or reflection angles as a function of incident angle and phase gradient of a meta-surface, in accordance with an embodiment of the present disclosure.

FIG. 8 is a schematic of an exemplary meta-surface with different meta-atom diameters that result in a “phase gradient” to steer an incident beam towards a given direction, in accordance with an embodiment of the present disclosure.

FIG. 9 is a plot of intensity transmission and phase of the transmission coefficient of a meta-surface device as a function of D/λ, in accordance with an embodiment of the present disclosure.

FIG. 10 is a schematic of a meta-surface lens designed to focus light with a specific wavelength λ to a distance f, in accordance with an embodiment of the present disclosure.

FIG. 11 illustrates a cross-sectional view of a display backplane prior to having micro LEDs bonded thereon, in accordance with an embodiment of the present disclosure.

FIGS. 12A-12C illustrate cross-sectional views of various display backplanes having micro LEDs bonded thereon, in accordance with an embodiment of the present disclosure.

FIG. 13A illustrates a cross-sectional view of assembly components (e.g., micro LED wafer and display backplane) during “selective bonding” of micro LEDs, in accordance with an embodiment of the present disclosure.

FIG. 13B illustrates a cross-sectional view of assembly components (e.g., micro LED wafer and display backplane) during “selective release” of micro LEDs, in accordance with an embodiment of the present disclosure.

FIG. 14 is a schematic of a conventional driving circuit for micro LEDs.

FIG. 15 is a schematic of a pixel structure with four redundant micro LED per subpixel, in accordance with an embodiment of the present disclosure.

FIG. 16 is a schematic of a “general” pixel architecture that can utilize a driver circuit together with the architecture type described in association with FIG. 15, in accordance with an embodiment of the present disclosure.

FIGS. 17A-17E illustrate cross-sectional views of various operations in a method of assembling a micro LED display, in accordance with an embodiment of the present disclosure.

FIG. 18 illustrates a schematic of micro LED display architecture, in accordance with an embodiment of the present disclosure.

FIG. 19A illustrates a cross-sectional view of a nanowire based LED highlighting certain layers of the LED, in accordance with an embodiment of the present disclosure.

FIG. 19B illustrates a cross-sectional view of a micro-LED composed of multiple nanowire LEDs, in accordance with an embodiment of the present disclosure.

FIG. 19C illustrates a cross-sectional view of a nanopyramid or micropyramid based LED highlighting certain layers of the LED, in accordance with an embodiment of the present disclosure.

FIG. 19D illustrates a cross-sectional view of an axial nanowire based LED highlighting certain layers of the LED, in accordance with an embodiment of the present disclosure.

FIG. 20 is a flow diagram illustrating a red green blue (RGB) display production process, in accordance with an embodiment of the present disclosure.

FIG. 21 is an electronic device having a display, in accordance with embodiments of the present disclosure.

### DESCRIPTION OF THE EMBODIMENTS

Micro light-emitting diode (LED) display fabrication processes and assembly apparatuses are described. In the following description, numerous specific details are set forth, such as specific material and structural regimes, in order to provide a thorough understanding of embodiments of the present disclosure. It will be apparent to one skilled in the art that embodiments of the present disclosure may be practiced without these specific details. In other instances, well-known features, such as single or dual damascene processing, are not described in detail in order to not unnecessarily obscure embodiments of the present disclosure. Furthermore, it is to be understood that the various embodiments shown in the Figures are illustrative representations and are not necessarily drawn to scale. In some cases, various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Certain terminology may also be used in the following description for the purpose of reference only, and thus are not intended to be limiting. For example, terms such as “upper”, “lower”, “above”, “below,” “bottom,” and “top” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

To provide context, displays based on inorganic micro LEDs (μLEDs) have attracted increasing attention for applications in emerging portable electronics and wearable computers such as head-mounted displays and wristwatches. Micro LEDs are typically first manufactured on Sapphire or silicon wafers (for example) and then transferred onto a display backplane glass substrate where on which active matrix thin-film transistors have been manufactured. The target acceptable defect density after such a transfer is approximately 1-2 ppm. This low defect density requirement may be achieved by transferring two micro LEDs for each color (red, green and blue), a so-called “redundancy strategy.” However, transferring more micro LEDs for redundancy may result in higher manufacturing cost.

One or more embodiments described herein are directed to devices and methods for micro LED assembly. In an embodiment, a device and method for fabricating full-color micro light emitting diode (μLED) displays by micro transfer assembly. Micro LED displays promise 2×-5× less power compared to organic LED (OLED) displays. The difference would result in a savings in battery life in mobile devices (e.g., notebook and converged mobility) and can enhance user experience. In an embodiment, micro LED displays described herein consume two-fold less power compared to organic LED (OLED) displays. Such a reduction in power consumption may provide an additional approximately 8 hours of battery life. Such a platform may even outperform platforms based on low power consumption central processing units (CPUs). Embodiments described herein may be associated with one or more advantages such as, but not limited to, high manufacturing yield, high manufacturing throughput (display per hour), and applicability for displays with a diagonal dimension ranging from 2 inches to 15.6 inches.

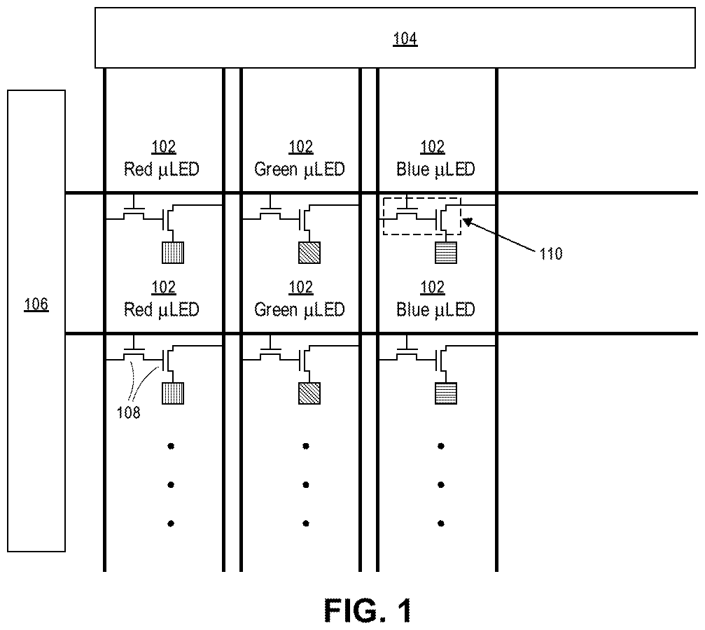

FIG. 1 is a schematic illustration of a micro LED display architecture, in accordance with an embodiment of the present disclosure. Referring to FIG. 1, micro LEDs 102 are arranged in a matrix. The micro LEDs are driven through “Data Driver” 104 and “Scan Driver” 106 chips. Thin film transistors 108 are used to make “pixel driver circuits” 110 for each micro LED. In an embodiment, the micro LEDs are fabricated on a silicon wafer then transferred to a glass substrate called “backplane” where the “pixel driver circuits” 110 have been fabricated using thin film transistors.

It is to be appreciated that, in a typical display, each pixel includes Red, Green and Blue (RGB) subpixels controlled independently by a matrix of transistors. For a μLED display, individual, small LED chips are used as the sub-pixel. Unlike organic LEDs (OLEDs), inorganic LEDs require high processing temperatures (e.g., greater than 1000° C.) and cannot be “grown” and patterned directly on top of a transistor matrix. In most cases, the micro LED chips are therefore manufactured separately and then positioned and connected to the transistor matrix via a pick and place process. Volume production at costs compatible with target applications still faces multiple engineering and manufacturing challenges. Such challenges may include LED epitaxy quality and homogeneity, efficiency of very small μLEDs, sidewall effects, massively parallel chip transfer technologies (e.g., pick and place) with position accuracy and high throughput, cost, handling of small die, etc., interconnects, color conversion, defect management, supply chain, and/or cost of production.

It is also to be appreciated that, like OLED, μLED technology is an emissive display technology. However, due to the inorganic nature of the emitting materials, their efficiency and narrow emission bands, μLEDs also offer the prospect of significantly improved performance in terms of energy consumption, color gamut, brightness, contrast (High Dynamic Range), long lifetime and environmental stability (e.g., no or low sensitivity to air and moisture), and/or compatibility with flexible backplane technologies to enable curved or flexible displays.

In a first aspect, in accordance with an embodiment of the present disclosure, micro LED displays and assembly apparatuses with spot light projectors are described.

To provide context, a state-of-the-art approach involves transfer with a stamp. For example, a stamp picks from the source wafer and the transfers to a target substrate where micro LED devices are assembled with driving electronics to provide a display. The approach, however, requires the need for pick up, bond, and release mechanisms. The approach is typically slow and expensive, and requires unique tooling. Furthermore, it may be expensive to manufacture displays larger than 2 inches in diagonal, and the process may be associated with low yield due to high defect density.

In accordance with one or more embodiments of the present disclosure, source wafers are used that have Red, Green and Blue (RGB) pixels or chips. Wafer-to-wafer type bonding equipment and process technologies may be used to directly transfer micro LEDs from a source wafer to a target display backplane substrate. In one embodiment, a multiple display pixel architecture is used to provide more than two micro LEDs per color per pixel, enabling a reduction in overall defect density on a produced display. In accordance with one or more embodiments, an assembly apparatus for fabricating micro LED displays is described.

Advantages of implementing embodiments described herein may include, but need not be limited to, one or more of (1) low manufacturing cost (e.g., as accomplished by transferring red-green-blue micro LED pixels in one pass from a silicon wafer to a “standard” display backplane, (2) high yield (e.g., a result of due micro LED redundancy and pixel architecture used, and/or (3) lower risk on equipment development since existing wafer-to-wafer bonding tools may be used.

In accordance with an embodiment of the present disclosure, a micro LED source wafer is brought into contact with a display substrate having metal bumps. The micro LED metal contacts and backplane metal bumps are opposite to one another. A bonding process involves orienting the two substrates (e.g., source wafer and display substrate) parallel to one another and compressing the two substrates together by applying a “force” on the outer surface of the carrier plate. The “force” may be applied to the center of the stack with a piston-type mechanism. In one such embodiment, a bonder apparatus provides precise bonding and is suitable for bonding one substrate pair at a time.

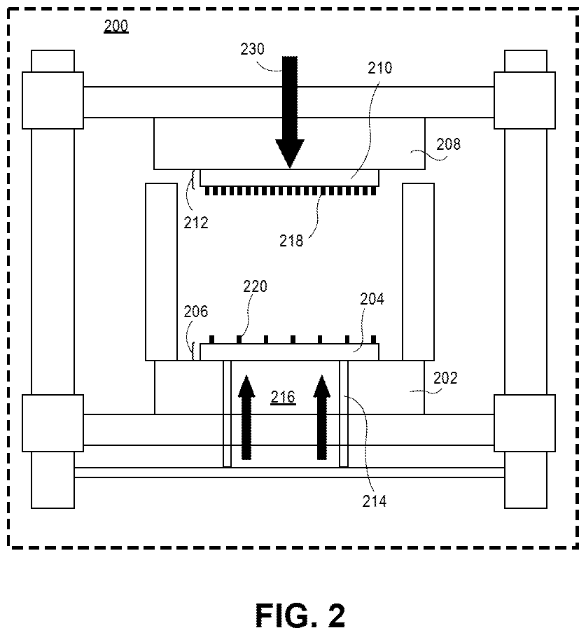

In a particular embodiment, upon fabrication of a micro-LED wafer, in order to fabricate a micro-LED based display, a transfer method is used in which micro-LEDs are transferred from a source wafer to a carrier wafer and then bonded with a target display backplane with the assistance of precise alignment, thermal compression bonding and selective release using an infra-red (IR) source as a source to release select one of the LEDs. In an example, FIG. 2 illustrates a cross-sectional view of a schematic of a display bonder apparatus, in accordance with an embodiment of the present disclosure.

Referring to FIG. 2, a display bonder apparatus 200 includes a first support 202 for holding a display backplane substrate 204 in a first position 206. A second support 208 is for holding a silicon wafer 210 in a second position 212. The second position 212 is over the first position 206. In one embodiment, a piston 214 is coupled to the first support 202. The piston 214 is for moving the display backplane substrate 204 from the first position 206 toward the second position 212. Further, the piston 214 applies a force 216 to the display backplane substrate 204 to bond light-emitting diode (LED) pixel elements 218 on the silicon wafer 210 to metal bumps 220 on the display backplane substrate 204. In an embodiment, the display bonder apparatus further includes an infra-red (IR) irradiation source 230 coupled to the second support 208.

In an embodiment, the display bonder apparatus 200 is used in a transfer process where a micro LED source wafer is brought into contact with a display substrate having metal bumps, such that the micro LED metal contacts and backplane metal bumps are opposite to one another. The bonding process involves orienting the two substrates (source wafer and display substrate) parallel to one another and compressing the two substrates together by applying force 216 on the outer surface of the display substrate. The force 216 may be applied to the center of the display substrate with a piston-type mechanism. The bonder apparatus 200 may provide precise bonding and may be suitable for bonding one substrate pair at a time. The bonding apparatus may be provided with a vacuum chamber (or any controlled atmosphere) and an aligner. The substrates may be aligned in the aligner, loaded in the controlled atmospheric chamber (vacuum/other), and thereafter bonded to each other.

In one embodiment, after bonding, the micro LEDs are selectively released from the silicon wafer to the display backplane. The selective release is carried out using infra-red (IR) laser irradiation through the silicon substrate (i.e., silicon is transparent to infra-red light). In a specific embodiment, the micro LEDs have a dimension of approximately 5 microns. In such an embodiment, in order to release only the micro LEDs that have been bonded to the backplane, a laser beam with a spot size as small as approximately 5 μm may need to be used.

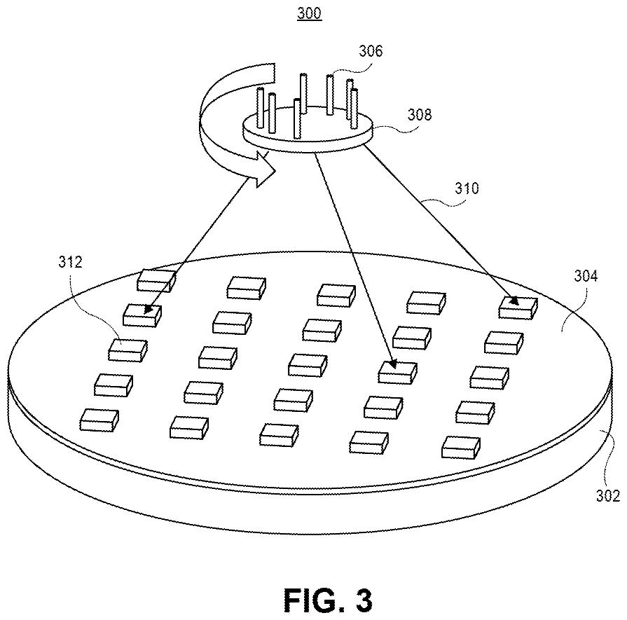

In accordance with one or more embodiments of the present disclosure, an infra-red laser module, such as described below in association with FIG. 3, is used to selectively release micro LEDs from a silicon wafer to a display backplane. In such an arrangement, multiple laser beams are irradiated on a transparent plate (i.e., transparent to infra-red) covered with an array of meta-surfaces that are used to “steer” and “focus” the laser beams to specific, pre-defined spots on the wafer in order to selectively release the micro LEDs on the other side of the wafer.

FIG. 3 illustrates a schematic view of an infra-red laser ablation module, in accordance with an embodiment of the present disclosure. Referring to FIG. 3, a laser ablation module 300 accommodates a micro LED wafer 302. The micro LED wafer 302 may include an anti-reflective coating 304. An infra-red (IR) laser source 306 is positioned above the micro LED wafer 302. The IR laser source 306 includes a rotating meta-surface 308. A laser beam 310 is emitted onto laser spots 312. In the illustration shown, in an embodiment, a silicon wafer is shown to illustrate the operation of a “Spot Light Projector.” Several meta-surfaces that steer and focus the infra-red laser source 306 are built on a rotating plate. In one embodiment, the rotating meta-surface produces a plurality of infra-red spots with small spot sizes (e.g., 5 μm) to release the micro LEDs on the other side of the wafer.

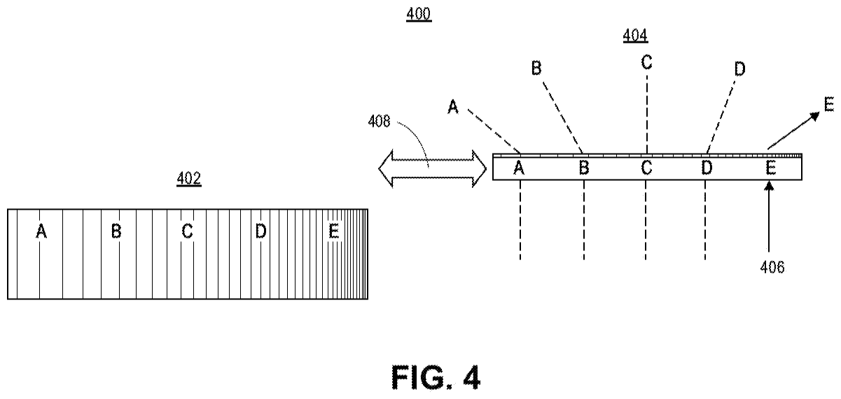

In an embodiment, an IR release is performed by implementing a sweep of a laser angle by shifting a surface consisting of arrays of anomalous refractive/reflective meta-surfaces, as exemplified in FIG. 4, described below. Each array of meta-surfaces may have a pre-determined angle through which they refract or reflect incident light. By changing the position of the incident light through various surface arrays, the incident beam may be swept through a wide angular range without splitting the beam. In one such embodiment, implementation of such an approach can preserve a high percentage of the beam power in the desired angle.

FIG. 4 illustrates a schematic of a meta-surface array used to sweep an angular position of a transmitted beam, in accordance with an embodiment of the present disclosure. Referring to FIG. 4, a head-on (out of plane) view 402 and a top-down view 404 of a grayscale represents meta-surface arrays that have varying angles of anomalous refraction. An incident laser 406 is transmitted through and refracted by the meta-surfaces at an angle pre-determined by the design of the meta-surface at each location. As the plate is shifted horizontally 408 (relative to the input laser 406), the incident beam 406 passes through different meta-surface arrays that refract the transmitted light at an angle determined by the meta-surface structures.

Embodiments described herein may be implemented to provide a display device and its nanowire components. Embodiments described herein may be implemented to provide pixel architecture with high redundancy. Embodiments described herein may be implemented to provide a display assembly apparatus. Embodiments described herein may be implemented to provide bonding between micro LEDs and a backplane using copper to copper (Cu-to-Cu) bonding or aluminum to aluminum (Al-to-Al) bonding (e.g., without solder or gold).

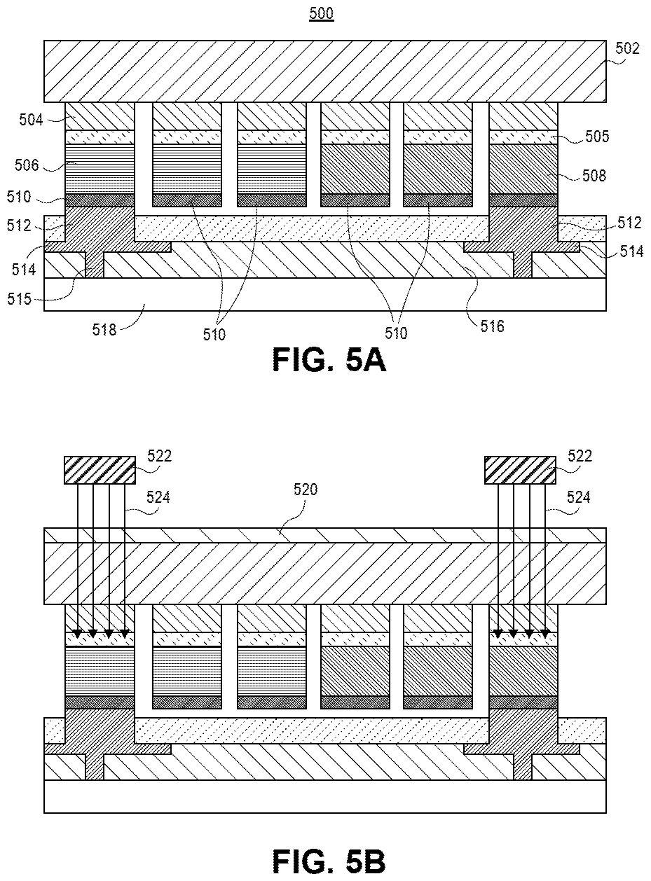

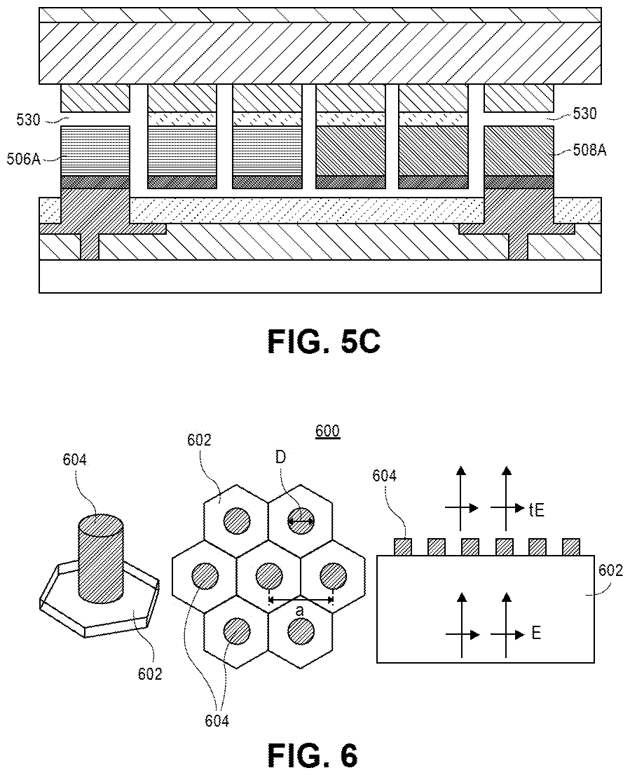

In an exemplary bonding process, FIGS. 5A-5C illustrate cross-sectional views of various operations in a method of assembling a micro LED display, in accordance with an embodiment of the present disclosure.

Referring to FIG. 5A, an LED substrate 502, such as a silicon wafer, has a patterned growth or nucleation layer 504 thereon, such as a patterned aluminum nitride layer. Individual micro LEDs 506/508 are associated with each pattern feature of the patterned growth or nucleation layer 504. In one embodiment, a first group of one type of micro LEDs 506, such as blue micro LEDs, is adjacent a second group of micro LEDs 508, such as green micro LEDs. A release layer 505, such as a metal nitride layer, may be between the individual micro LEDs 506/508 and the associated pattern feature of the patterned growth or nucleation layer 504, as is depicted. A metal bonding layer 510, such as a copper or aluminum layer, is on each of the individual micro LEDs 506/508.

Referring again to FIG. 5A, a backplane 518 is opposite the LED substrate 502. The backplane 518 may include a dielectric layer 516 having conductive features therein. The conductive features may include reflective plates 514 and associated vias 515. Metal pads or bumps 512 are on the reflective plates 514. In an embodiment, metal bonding layer 510 is a copper layer and metal pads or bumps 512 are copper pads or bumps. In another embodiment, metal bonding layer 510 is an aluminum layer and metal pads or bumps 512 are aluminum pads or bumps.

Referring again to FIG. 5A, selected ones of the individual micro LEDs 506/508 are bonded to a corresponding metal pads or bumps 512 to provide a micro LED wafer bonded to a display backplane. In one such embodiment, thermo-compression bonding (TCB) is used to provide ones of the individual micro LEDs 506/508 bonded to the corresponding metal pads or bumps 512.

Referring to FIG. 5B, an anti-reflective coating 520 is formed on the LED substrate 502. One or more infra-red (IR) lasers 522 supplies IR irradiation 524 directed through the LED substrate 502 and onto the release layer 505 of the selected ones of the individual micro LEDs 506/508. The IR laser or lasers may as described above in association with laser ablation module 300. In an embodiment, the IR irradiation 524 irradiates release layer 505 of the selected ones of the individual micro LEDs 506/508.

Referring to FIG. 5C, the LED substrate 502 is then released from the display backplane 518 upon ablation of release layer 505 at locations 530 of the selected ones of the individual micro LEDs 506/508. The selective release leaves micro LEDs 506A and 508A remaining as bonded to the display backplane 518. The remaining micro LEDs on LED substrate 502 may then be bonded to another display back plane.

In accordance with one or more embodiments described herein, meta-surfaces are defined as nanostructured devices composed of arrays of subwavelength scatterers (or meta-atoms) that manipulate the wave-front, polarization, or intensity of light. Like most other diffractive optical devices, meta-surfaces are designed to operate optimally at one wavelength. In one embodiment, dielectric transmit-arrays are the most versatile meta-surfaces because they provide high transmission and subwavelength spatial control of both polarization and phase. Such devices may be based on subwavelength arrays of high refractive-index dielectric nano-resonators (scatterers) with different geometries, fabricated on a planar substrate. Scatterers with various geometries may be implemented to impart different phases to the transmitted light, shaping its wave-front to the desired form. For meta-atoms such as rectangular dielectric cuboid, a form of birefringence may be induced, and the meta-surface optical response may be highly sensitive to the polarization of the incident radiation. Conversely, when centrosymmetric subwavelength features such as pillars or cylinders are involved, the meta-surface device can be operated with non-polarized light.

In an embodiment, for operation of a meta-surface such as dielectric nanodisks, incident radiation/light brings both electric and magnetic responses of comparable strengths. The coupling of incoming light to the electric field's circular displacement current may result in a strong magnetic dipole resonance. The magnetic resonance occurs when the wavelength inside the particle becomes comparable to its spatial dimension, i.e., when D≈λ/n, where n is the refractive index of the nanoparticle material, D is the nanoparticle diameter, and λ is the light's wavelength.

FIG. 6 illustrates a schematic 600 of an angled view of a meta-atom (cylindrical nanopost) 604 on a dielectric 602 (left), a top view of the meta-surface device composed of meta-atoms on a hexagonal lattice showing geometrical parameters such as spacing “a” between nanoposts (center), and a cross-sectional view of a meta-surface device (right), in accordance with an embodiment of the present disclosure. It is to be appreciated that other lattice types may also be used. In one embodiment, the amplitude and phase of transmitted light (tE) depends on the ratio D/λ for a given incident light (E).

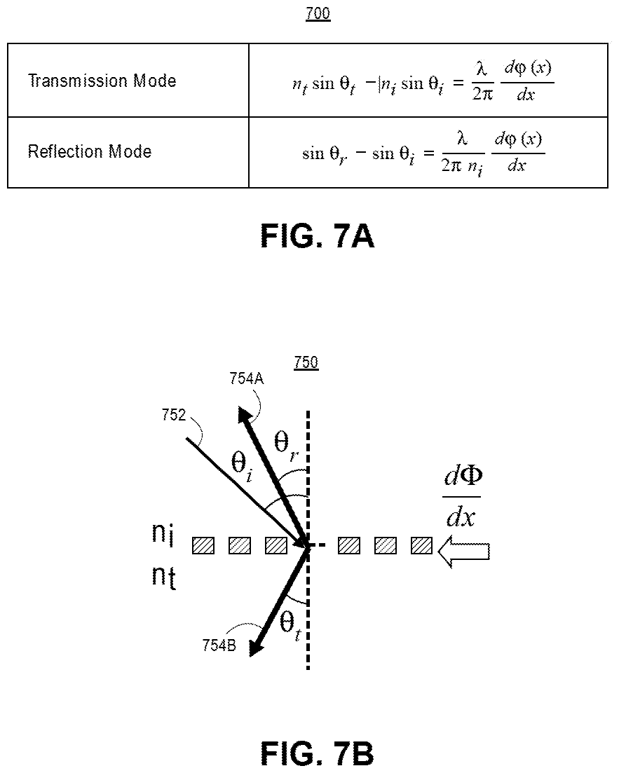

It is to be appreciated that an important aspect of applying meta-surface technology for implementations described herein is the use of a “transparent” material in order to maximize the efficiency (and minimize optical loss) for a given wavelength of light. For example, in one embodiment, titanium oxide is used as a meta-surface material to provide >90% optical efficiencies. FIG. 7A includes a table 700 of governing equations for transmission mode and reflection mode, in accordance with an embodiment of the present disclosure. FIG. 7B is an associated diagram 750 used to deduce the transmission or reflection angles as a function of incident angle and phase gradient of a meta-surface, in accordance with an embodiment of the present disclosure. An incidence 752, an anomalous reflection 754A, and an anomalous refraction 754B are shown. In one embodiment, the gradient of the phase is tuned by the distribution of meta-atoms diameters on the surface.

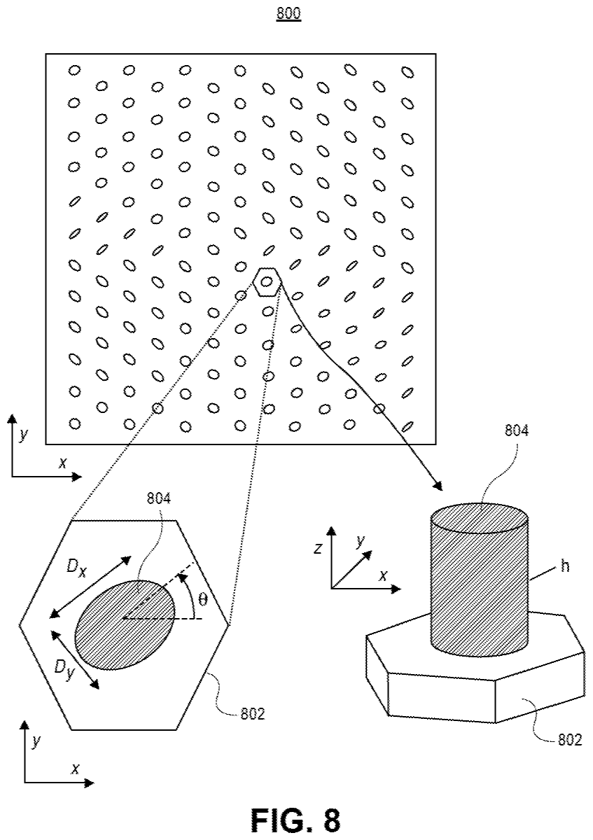

An example of a beam steering meta-surface design that is polarization insensitive, FIG. 8 is a schematic of an exemplary meta-surface 800 with different meta-atom diameters that result in a “phase gradient” to steer an incident beam towards a given direction, in accordance with an embodiment of the present disclosure. Referring to FIG. 8, the meta-surface 800 includes a plurality of unit cells 802, each including a nanoparticle.

In accordance with an embodiment of the present disclosure, meta-surface lenses or meta-material lenses provide an alternative option to conventional and Fresnel lenses where weight and thickness (i.e., compactness) are of high value to the end user. Meta-surface lenses may be monolithically integrated on photodetectors in order to achieve high image quality and reduces manufacturing and assembly cost. In an embodiment, for metamaterial lenses, one may expect performance that approaches diffraction-limited optics as the nano-manufacturing methods and materials are accurate enough to achieve and hold such accuracy. One of the limits of precision of an optical system can be related to the fact that the wavelength of light, although very small, is in fact finite. This imposes the absolute limit as to how fine-focused rays of light may be, even if the lens is “perfect.” If a lens is sufficiently accurate that its imperfections contribute less to image degradation than the wavelength of light, the lens may be referred to as being “diffraction limited.”

In accordance with an embodiment of the present disclosure, a select dielectric material is used to fabricate all-dielectric meta-surface lenses. To provide context, meta-surfaces were originally designed and fabricated by arrays of metallic nanoparticles (resonators), with Ohmic losses that are significantly huge and strongly affect the converting efficiency, especially in near-infra-red and visible wavelength range. By contrast, in an embodiment, all-dielectric meta-surface lenses are implemented to avoid Ohmic losses. An efficient light manipulation can provide simultaneous control of its electric and magnetic components. Owing to their low losses in the visible and near-infra-red spectral range, all-dielectric meta-surfaces can be implemented to enable the realization of practically absorption-less functional devices for wave-front manipulation.

It is to be appreciated that dielectric nanoparticles may exhibit strong localized resonances in the optical spectral range, which can be tailored via their size, shape, and material composition. Importantly, for nanoparticles composed of high refractive-index dielectric materials, e.g., Silicon (Si), Gallium Phosphide (GaP), and Titanium Oxide (TiO₂), such resonances can be of both electric and magnetic multipolar character, the latter originating from the optical excitation of circular displacement currents inside the dielectric nanoparticles. In an embodiment, the combination of low losses and both electric and magnetic dipolar resonances with resonance properties that can be tailored provides engineered meta-surfaces for wave-front and dispersion engineering with near-unity efficiency in transmission. In one embodiment, the field enhancement and quality factor of resonances benefit when the particle has a large index, as a larger index contrast can translate to a smaller radiation leakage from the nanoparticles. In addition, in high-index dielectric nanoparticles, strong directional scattering of light can be realized due to interference of magnetic and electric dipole responses excited simultaneously with comparable strength.

It is to be appreciated that, in accordance with one or more embodiments of the present disclosure, the implications of having to use high refractive index dielectric materials can mean that a diameter of the nanoparticles has to be subwavelength in size (e.g., according to the condition: D≈λ/n). Thus, design principles of for monochromatic focusing meta-surface lenses may be based on the need that each nano-post impart the required phase at a given coordinate (x, y) on the meta-lens surface with maximum transmission efficiency in order to realize a high performance transmissive meta-lens, according to equation (A) below:

φ(x,y)=(2π/λ)(f−√x2+y2+f2) (A)

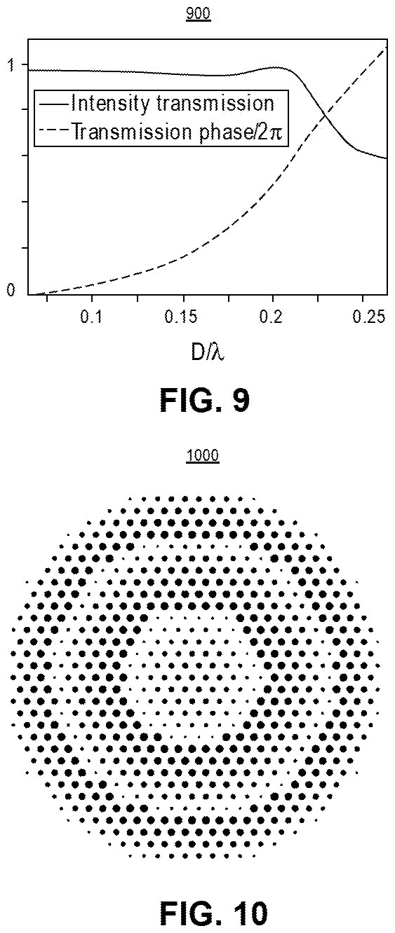

For a target focal length (f), a meta-lens can be manufactured by nanoposts with different diameters to provide a phase that varies from 0 to 2π for the light wave incident on coordinate (x, y) according to the relationship shown in FIG. 9, where a schematic of an example meta-surface focusing lens is shown in FIG. 10.

FIG. 9 is a plot 900 of intensity transmission and phase of the transmission coefficient of a meta-surface device as a function of D/λ, in accordance with an embodiment of the present disclosure. It is to be appreciated that the height of the nanoposts≈λ/2. For simulations, a uniform array of meta-atoms with a given diameter is illuminated with a plane wave at the wavelength of interest, and the transmission amplitude and phase are calculated. Rigorous Coupled Wave Analysis (RCWA) was used to perform the simulations. For near IR (NIR) wavelength of 850 nm, 400 nm high nanoposts with diameters in the range of 64 nm to 210 nm can change the phase by full 2π. That is, the relationship shows that nanolithography fabrication is likely required for manufacturing meta-surface devices.

FIG. 10 is a schematic of a meta-surface lens 1000 designed to focus light with a specific wavelength λ a distance f, in accordance with an embodiment of the present disclosure. The focusing function results from the spatial variation of the meta-atom diameter as a function of coordinate (x, y) according to Equation (A) and the relationship shown in plot 900.

In an embodiment, fabrication of meta-surface lenses begins with a flat wafer, and decorates the surface with carefully designed nanoparticles. The nanoparticles alter the phase of light as it passes through or reflects, creating a new wave-front. Achieving full control over the phase of light may require precise, high-aspect-ratio nanostructures, which are in turn may require the use of nanofabrication methods. In an embodiment, meta-surface devices enable wafer-scale production of lithographically defined thin diffractive optical elements using conventional nano-manufacturing techniques.

In a second aspect, in accordance with an embodiment of the present disclosure, structures for fabricating micro LED displays are described.

To provide context, a conventional “pixel bank” structure that was originally proposed for use with a pick and bond mass transfer method is designed to receive micro LEDs transferred to the backplane using a “stamp”. Such a “pixel bank” structure, however, may not be suitable for the “direct transfer method” for mass transfer of micro LEDs from source wafers to a display backplane.

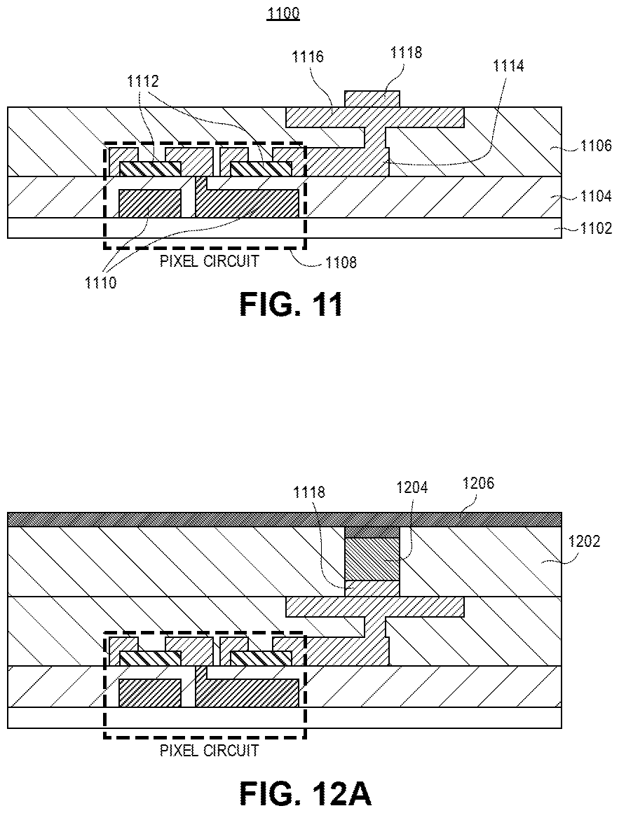

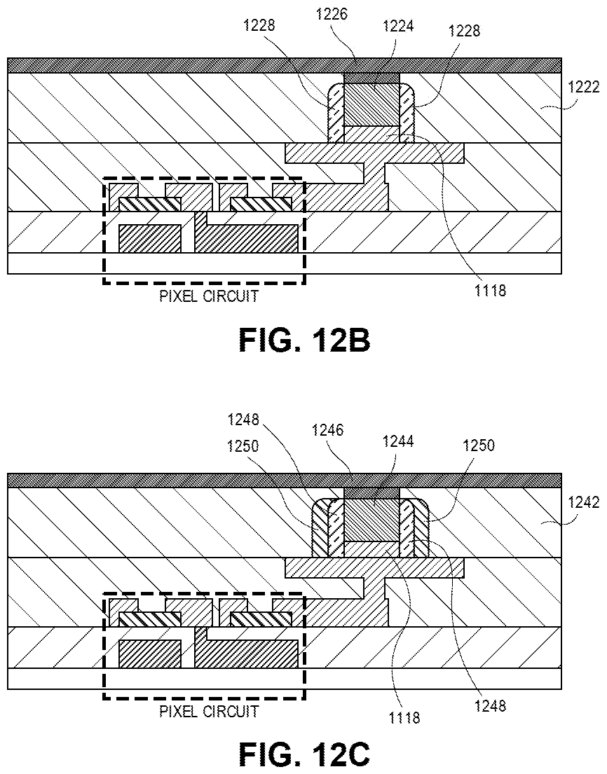

In accordance with an embodiment of the present disclosure, a method and structure for receiving a micro device on a receiving substrate are disclosed. Micro LEDs may be bonded to a backplane that has protrusions of electrically conductive pads that are sitting on a large light reflective metallic plate, as depicted in FIG. 11. After bonding of the micro LEDs, one or more high refractive index spacers are fabricated around the micro LED to improve the light extraction efficiency and to control the output beam, as shown in FIGS. 12A-12C. It is to be appreciated that traditional technologies for transferring of devices include transfer by wafer bonding from a transfer wafer to a receiving wafer. One such implementation is “direct printing” involving one bonding operation of an array of devices from a transfer wafer to a receiving wafer, followed by removal of the transfer wafer. By contrast, embodiments described herein involve the direct bonding of micro LEDs on a display backplane followed be selective removal of the micro LEDs (as opposed to removing the whole wafer).

FIG. 11 illustrates a cross-sectional view of a display backplane prior to having micro LEDs bonded thereon, in accordance with an embodiment of the present disclosure.

Referring to FIG. 11, a backplane structure 1100 includes a glass substrate 1102 having an insulating layer 1104 thereon. A planarization oxide layer 1106 may be on the insulating layer 1104. Pixel thin film transistor (TFT) circuits 1108 are included in and on the insulating layer 1104. Each of the pixel TFT circuits 1108 includes gate electrodes 1110, such as metal gate electrodes, and channels 1112. A portion of the insulating layer 1104 may act as a gate dielectric for each of the pixel TFT circuits 1108.

In an embodiment, the pixel TFT circuits 1108 are low temperature polysilicon (LTPS)-type TFTs. In another embodiment, the pixel TFT circuits 1108 are IZGO TFTs or IGZO-type TFTs, where the channel 1112 of each of the pixel TFT circuits 1108 includes a semiconducting oxide material. In an embodiment, the semiconducting oxide material is an IGZO layer that has a gallium to indium ratio of 1:1, a gallium to indium ratio greater than 1 (e.g., 2:1, 3:1, 4:1, 5:1, 6:1, 7:1, 8:1, 9:1, or 10:1), or a gallium to indium ratio less than 1 (e.g., 1:2, 1:3, 1:4, 1:5, 1:6, 1:7, 1:8, 1:9, or 1:10). A low indium content IGZO may refer to IGZO having more gallium than indium (e.g., with a gallium to indium ratio greater than 1:1), and may also be referred to as high gallium content IGZO. Similarly, low gallium content IGZO may refer to IGZO having more indium than gallium (e.g., with a gallium to indium ratio less than 1:1), and may also be referred to as high indium content IGZO. In another embodiment, the semiconducting oxide material is or includes a material such as tin oxide, antimony oxide, indium oxide, indium tin oxide, titanium oxide, zinc oxide, indium zinc oxide, gallium oxide, titanium oxynitride, ruthenium oxide, or tungsten oxide.

In an embodiment, the semiconducting oxide material is an amorphous, crystalline, or semi crystalline oxide semiconductor, such as an amorphous, crystalline, or semi crystalline oxide semiconductor IGZO layer. The semiconducting oxide material may be formed using a low-temperature deposition process, such as physical vapor deposition (PVD) (e.g., sputtering), atomic layer deposition (ALD), or chemical vapor deposition (CVD). The ability to deposit the semiconducting oxide material at temperatures low enough to be compatible with back-end manufacturing processes represents a particular advantage. The semiconducting oxide material may be deposited on sidewalls or conformably on any desired structure to a precise thickness, allowing the manufacture of transistors having any desired geometry.

In an embodiment, gate electrodes 1110 includes at least one P-type work function metal or N-type work function metal. For a P-type transistors, metals that may be used for the gate electrode 1110 may include, but are not limited to, ruthenium, palladium, platinum, cobalt, nickel, and conductive metal oxides (e.g., ruthenium oxide). For an N-type transistor, metals that may be used for the gate electrode 1110 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide).

The planarization oxide layer 1106 may have conductive features therein. The conductive features may include one or more interconnects 1114 and associated reflective plate or mirror 1116. Metal pads or bumps 1118 are on the reflective plate or mirror 1116. In an embodiment, metal pads or bumps 1118 are copper or aluminum pads or bumps. The structure of FIG. 11 may be referred to as a back plane.

A micro LED may be bonded to the backplane structure of FIG. 11. In an example, FIGS. 12A-12C illustrate cross-sectional views of various display backplanes having micro LEDs bonded thereon, in accordance with an embodiment of the present disclosure.

Referring to FIG. 12A, a front plane includes a micro LED 1204 bonded to a corresponding metal pads or bumps 1118 coupled to the back plane of FIG. 11. A second planarization oxide or insulating layer 1202 may be formed to surround the bonded structure. A transparent electrode 1206, such as an indium tin oxide (ITO) layer, is formed thereon with a window exposing the micro LED 1204. The transparent electrode 1206 may function as a common cathode. In an embodiment, the micro LED 1204 is a green micro LED, a blue micro LED, or a red micro LED.

Referring to FIG. 12B, a front plane includes a micro LED 1224 bonded to a corresponding metal pads or bumps 1118 coupled to the back plane of FIG. 11. A spacer 1228 is formed adjacent sidewalls of the micro LED 1224. In one embodiment, the spacer 1228 is a high refractive index material such as titanium oxide (e.g., TiO₂). A second planarization oxide or insulating layer 1222 may be formed to surround the spacer 1228 of the bonded structure. A transparent electrode 1226, such as an indium tin oxide (ITO) layer, is formed thereon with a window exposing the micro LED 1224. The transparent electrode 1226 may function as a common cathode. In an embodiment, the micro LED 1224 is a green micro LED, a blue micro LED, or a red micro LED.

Referring to FIG. 12C, a front plane includes a micro LED 1244 bonded to a corresponding metal pads or bumps 1118 coupled to the back plane of FIG. 11. A first spacer 1248 is formed adjacent sidewalls of the micro LED 1244. A second spacer 1250 is formed adjacent the first spacer 1248. In one embodiment, the first spacer 1248 and the second spacer 1250 are each a high refractive index material, such as titanium oxide (e.g., TiO₂) and/or silicon nitride (Si₃N₄) in either order. A second planarization oxide or insulating layer 1242 may be formed to surround the second spacer 1250 of the bonded structure. A transparent electrode 1246, such as an indium tin oxide (ITO) layer, is formed thereon with a window exposing the micro LED 1244. The transparent electrode 1246 may function as a common cathode. In an embodiment, the micro LED 1244 is a green micro LED, a blue micro LED, or a red micro LED.

Advantages to implementing one or more embodiments described herein include one or more of (1) enabling a “direct transfer method” for mass transfer of micro LEDs from source wafer to display backplane with high yield and low manufacturing cost, (2) high light extraction efficiency with lower power consumption, (3) control of a radiation pattern from a micro LED to the observer, and/or (4) realizing the promised power reductions with micro LED displays based on the fabrication of LEDs with high power efficacies for the three color LED emitters.

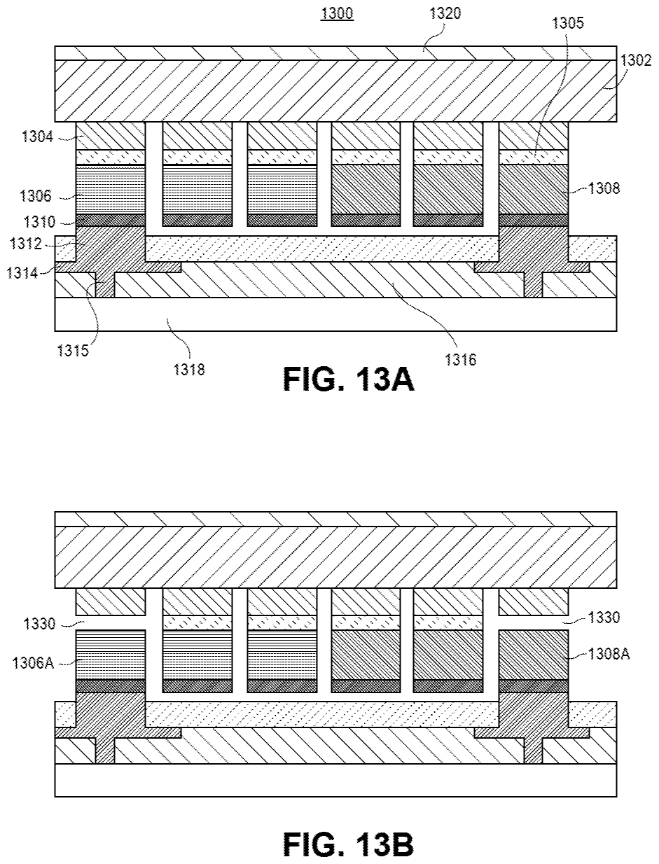

FIG. 13A illustrates a cross-sectional view of assembly components (e.g., micro LED wafer and display backplane) during “selective bonding” of micro LEDs, in accordance with an embodiment of the present disclosure.

Referring to FIG. 13A, an LED substrate 1302, such as a silicon wafer, has a patterned growth or nucleation layer 1304 thereon, such as a patterned aluminum nitride layer. Individual micro LEDs 1306/1308 are associated with each pattern feature of the patterned growth or nucleation layer 1304. In one embodiment, a first group of one type of micro LEDs 1306, such as blue micro LEDs, is adjacent a second group of micro LEDs 1308, such as green micro LEDs. A release layer 1305, such as a metal nitride layer, may be between the individual micro LEDs 1306/1308 and the associated pattern feature of the patterned growth or nucleation layer 1304, as is depicted. A metal bonding layer 1310, such as a copper or aluminum layer, is on each of the individual micro LEDs 1306/1308. A backplane 1318 is opposite the LED substrate 1302. The backplane 1318 may include a dielectric layer 1316 having conductive features therein. The conductive features may include reflective plates 1314 and associated vias 1315. Metal pads or bumps 1312 are on the reflective plates 1314. In an embodiment, metal bonding layer 1310 is a copper layer and metal pads or bumps 1312 are copper pads or bumps. In another embodiment, metal bonding layer 1310 is an aluminum layer and metal pads or bumps 1312 are aluminum pads or bumps. Selected ones of the individual micro LEDs 1306/1308 are bonded to a corresponding metal pads or bumps 1312 to provide a micro LED wafer bonded to a display backplane. An anti-reflective coating 1320 is formed on the LED substrate 1302.

FIG. 13B illustrates a cross-sectional view of assembly components (e.g., micro LED wafer and display backplane) during “selective release” of micro LEDs, in accordance with an embodiment of the present disclosure. The LED substrate 1302 is then released from the display backplane 1318 upon removal of release layer 1305 at locations 1330 of the selected ones of the individual micro LEDs 1306/1308. The selective release leaves micro LEDs 1306A and 1308A remaining as bonded to the display backplane 1318. The remaining micro LEDs on LED substrate 1302 may then be bonded to another display back plane.

In a third aspect, in accordance with an embodiment of the present disclosure, fault-tolerant pixel structures for high yield micro LED displays are described. Embodiments may be implemented to provide low-power and high image quality micro LED displays that maybe suitable for use in, e.g., Notebook PC computing devices.

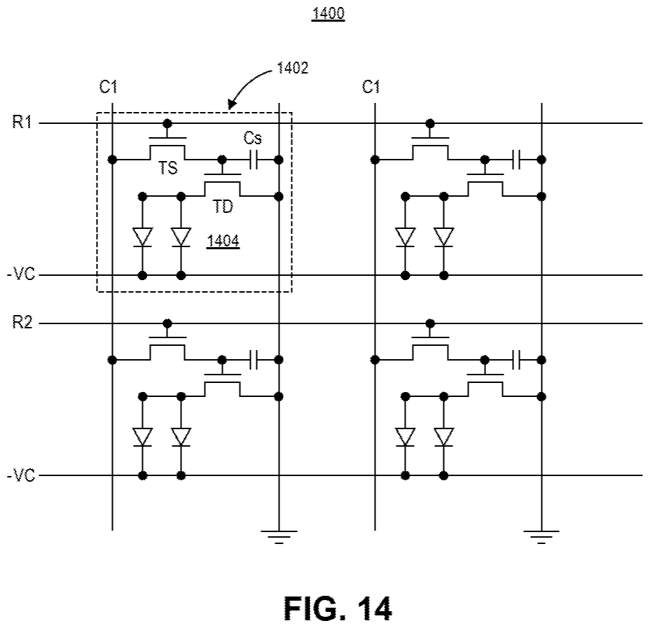

To provide context, conventionally, a pixel of the active matrix micro LED display has been generally constructed as shown in FIG. 14. FIG. 14 is a schematic 1400 of a conventional driving circuit for micro LEDs. The amount of luminescence of the micro LED 1404 is controlled by the data signal, and thereby gray-level on the display is controlled. This is a so-called analog gray-scale method, in which the gray-level is controlled by a change in the amplitude of the signal. A monochromatic display is shown for simplicity, but for full-color display each pixel 1402 is composed of three subpixels for red, green, and blue micro LEDs. Two micro LEDs are connected in parallel to each driving circuit to provide a fault-tolerant design.

In FIG. 14, reference character TS designates a TFT that functions as a switching element (hereinafter, referred to as switching TFT), TD designates a TFT that functions as an element (current controlling element) to control a current supplied to micro LED (hereinafter, referred to as current controlling TFT), and Cs designates a capacitor (capacitance storage). The switching TFT (TS) is connected to a gate wiring line R1 and a source wiring line C1 (data wiring line). The drain of the current controlling TFT is connected to the micro LED, and the source thereof is connected to a “ground”. When the gate wiring line R1 is selected, the gate of the switching TFT is opened, the data signal of the source wiring line is then stored in the capacitor Cs, and the gate of the current controlling TFT (TD) is opened. After the gate of the switching TFT is closed, the gate of the current controlling TFT is kept open by the charge stored in the capacitor Cs. During that interval, the micro LED emits light. The amount of luminescence of the micro LED changes according to the amount of a flowing current. At this time, the amount of current supplied to the micro LED is controlled by the gate voltage of the current controlling TFT. Conventional solutions rely on using two micro LEDs connected in parallel to provide redundancy in case one of the micro LEDs is open circuit, the other will probably work, thus providing a way to reduce number of defective pixels per display below the maximum allowed specifications, which is typically 8 pixels in displays with 4 million pixels.

It is to be appreciated that the fault-tolerant design shown in FIG. 14 may suffer from two issues: (1) if one of the two micro LEDs 1404 connected in parallel is short circuit, the pixel 1402 will be counted as defective, even if the second micro LED functions properly. The use of only two redundant micro LEDs to achieve 80% display yield requires the achievement of 99.99% for both micro transfer yield and wafer die yield. These targets are very aggressive and may not be achievable.

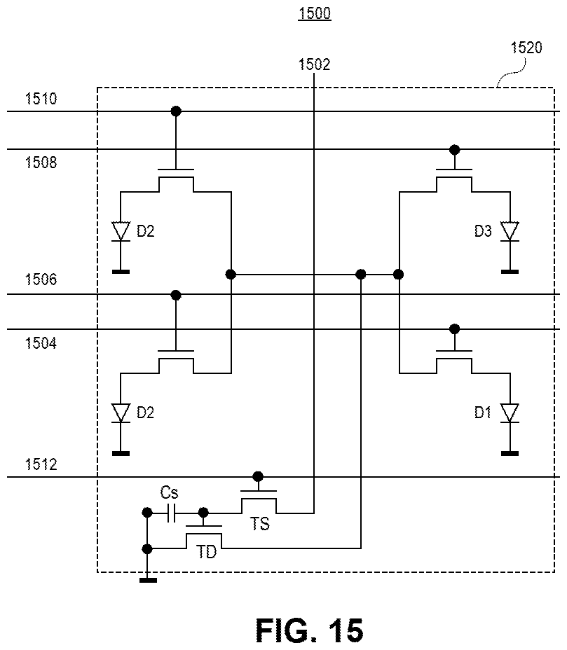

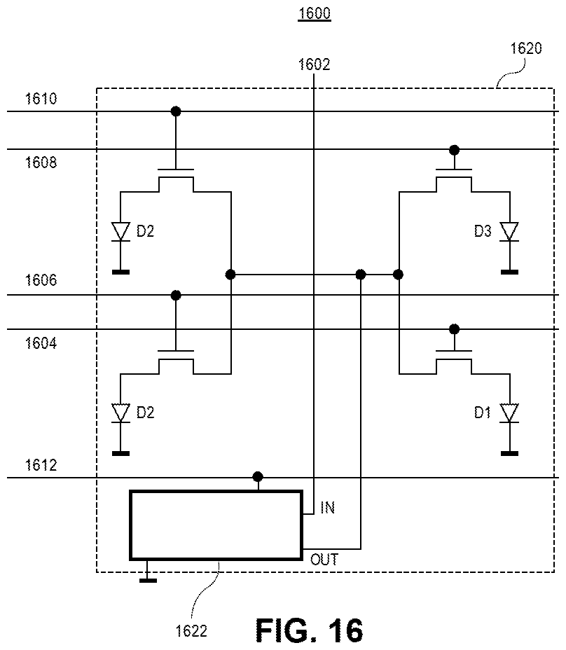

In accordance with one or more embodiments of the present disclosure, a pixel structure is disclosed herein that provides a much improved fault-tolerant design and thus high display yield (>80%) for relatively low micro transfer yield and wafer die yield of 99.5% if the number of micro LEDs per subpixel=3. In one embodiment, a pixel structure disclosed herein provides a much improved fault-tolerant design and thus high display yield (>80%) for relatively low micro transfer yield and wafer die yield of 99% if the number of micro LEDs per subpixel=4. An exemplary design is shown in FIG. 15. Compared to FIG. 14, a refresh rate=4×60 Hz=240 Hz may be used to avoid the scenario when one of the redundant micro LEDs is short circuited. A general pixel circuit architecture is shown in FIG. 16 to accommodate for any driver circuit (e.g., other than the one composed of TS, TD, and CS).

FIG. 15 is a schematic of a pixel structure 1500 with four redundant micro LEDs per subpixel 1520, in accordance with an embodiment of the present disclosure. All micro LEDs (D1-D4) are of the same color. For RGB colors, 12 micro LEDs are needed per pixel. In this architecture, compared to FIG. 14, a refresh rate=4×60 Hz=240 Hz may be used to avoid the scenario when one of the redundant micro LEDs is short circuited. The driver circuit composed of TS, TD and Cs drives four micro LEDs sequentially with the same “data” provided by the DATA LINE 1502. Also includes are SCAN LINE 1 (1504), SCAN LINE 2 (1506), SCAN LINE 3 (1508), SCAN LINE 4 (1510), and a PROGRAM LINE (1512).

FIG. 16 is a schematic of a “general” pixel architecture 1600 that can utilize a driver circuit 1622 together with the architecture type described in association with FIG. 15, in accordance with an embodiment of the present disclosure. The architecture 1600 includes four redundant micro LEDs per subpixel 1620, in accordance with an embodiment of the present disclosure. All micro LEDs (D1-D4) are of the same color. The driver circuit composed of TS, TD and Cs drives four micro LEDs sequentially with the same “data” provided by the DATA LINE 1602. Also includes are SCAN LINE 1 (1604), SCAN LINE 2 (1606), SCAN LINE 3 (1608), SCAN LINE 4 (1610), and a PROGRAM LINE (1612). Advantages of implementing embodiments disclosed herein may provide micro LED displays with ultralow pixel defect density (i.e., high manufacturing yield).

In an embodiment, the architectures shown in FIGS. 15 and 16 are fault-tolerant pixel architectures. The use of four micro LEDs per subpixel provides a high manufacturing yield. The circuit architecture provided in this disclosure accommodates the scenario for when at least one of the micro LEDs is short circuited.

In another aspect, for micro LED displays, if the whole display is required to be fault-free, the yield will be close to zero. The yield can be increased by adding spare (redundant) subpixels to the design and by accepting those displays that have less than a non-zero number of faulty pixels. The desired yield (cost) level determines the optimal amount of redundancy to be incorporated into the display. In an embodiment disclosed herein, a manufacturing yield model for micro LED displays with redundant subpixels taken into consideration. The model is used to estimate the required micro LED wafer yield in order to achieve a specific yield for micro LED displays using the Direct Transfer Method. The input to the model are display size, resolution and maximum allowable defective pixels on the display.

In an embodiment, the introduction of redundancy in a micro LED display pixel results in yield improvement and fabrication-cost reduction. The estimation of yield improvement requires a fault-distribution model. There are two representative models, a Poisson distribution model and negative-binomial model, which are often used for the yield analysis of memory LSIs. A Poisson distribution model is often used for yield analysis because of its mathematical simplicity. It is useful for rough yield estimation or the comparison of redundancy techniques.

First, consider a display with N “pixels”. If faults (bad pixels) are randomly distributed on the display, the probability of a pixel being faulty, p, is independent of the probability of other pixels being faulty or non-faulty. Therefore, the probability that k pixels are faulty and (N−k) pixels are not faulty is expressed as the product of their probabilities:

p^{k}(1−p)^{N-k}

The number of cases of selecting k faulty pixels out of N pixels is expressed by

$$\frac{N ( N - 1 ) … ( N - k + 1 )}{k !} = ( \begin{matrix}N \\ k\end{matrix} ) = \frac{N !}{( N - k ) ! k !} \qquad ( 2 )$$

Thus the probability of existing faulty pixels in the display can be expressed by (which is called binomial distribution)

$$P ( k ) = ( \begin{matrix}N \\ k\end{matrix} ) {{p}^{k} ( 1 - p )}^{N - k} \qquad ( 3 )$$

Usually, N is very large and p is very small.
If we define

$$As N -> ∞ then \begin{matrix}λ = N p & ( 4 ) \\ P ( k ) = \frac{{λ}^{k} exp ( - λ )}{( k ) !} & ( 5 )\end{matrix}$$

This is called the Poisson distribution.
The average k of the number of faulty pixels are expressed as

k̅=λ. (6)

Thus, the parameter λ is equal to the average number of faults
The probability of a display having no faulty pixels (raw yield, i.e., yield without redundancy) is expressed as

P(0)=exp(−λ) (7)

The probability of having faults less than or equal to m is given by the yield

$${Y}_{m} = {\sum }_{k = 0}^{m} P ( k ) \qquad ( 8 )$$

Yield improvement with redundancy:

The probability that a micro LED is defect-free after DTM is given by

p=exp(−λ)×exp(−λ_{b})

Where

λ=A_{LED}D

λ_{b}=A_{LED}D_{b}

Y_{DTM}=exp(−λ_{b})

Y_{w}=exp(−λ)

With A_{LED} is the area of the micro LED, D is the defect density on the micro LED source wafer (defects/cm²), D_{b} is the defect density of bonds due to the DTM process (defects/cm), Y_{w} is the wafer die yield, and Y_{DTM} is the micro transfer yield.
The probability that a micro LED is defective is

q=1−p

The probability of k defective micro LEDs out of R in one pixel

$$P ( k ) = ( \begin{matrix}R \\ k\end{matrix} ) {{q}^{k} ( 1 - q )}^{R - k}$$

The probability of up to R−1 defective micro LEDs is

$${\sum }_{k = 0}^{R - 1} ( \begin{matrix}R \\ k\end{matrix} ) {{q}^{k} ( 1 - q )}^{R - k}$$

The probability of defect-free pixel is

$${( {\sum }_{k = 0}^{R - 1} ( \begin{matrix}R \\ k\end{matrix} ) {{q}^{k} ( 1 - q )}^{R - k} )}^{3}$$

The probability of defective pixel is

$${p}_{p} = 1 - {( {\sum }_{k = 0}^{R - 1} ( \begin{matrix}R \\ k\end{matrix} ) {{q}^{k} ( 1 - q )}^{R - k} )}^{3}$$

The probability that there are up to m defective pixels on the display

$$Y = {\sum }_{i = 0}^{m} ( \begin{matrix}N \\ i\end{matrix} ) {{p}_{p}^{i} ( 1 - {p}_{p} )}^{N - i} \qquad ( 9 )$$

Example model results: In one example, display yield are calculated using Equation (9) by setting the micro LED die wafer yield to 99.3% and the DTM transfer yield to 99.9%. The calculations are performed for different levels of redundancy (1, 2, 3, 4), QHD display resolution, and different diagonal size (5.5″, 8″, 11.6″, 13.3″ and 15.6″). In his case, a reasonably high display yield is obtained when redundancy is 3, and excellent yield when the redundancy is 4. A redundancy level of 2 may not be sufficient to produce displays with acceptable yields for this display with such wafer die yield and micro transfer yield.

In another model results example, the wafer die yield and DTM yield to achieve a specific target display yield of 80% are shown in FIG. 4 for a fixed redundancy of 3, DPM=2, QHD resolution, and 13.3″ display diagonal. As a result, higher DTM yield allows for smaller wafer die yield to meet the desired display yield target. Calculated wafer die yield versus DTM yield that will achieve a target display yield of 80%: the redundancy is fixed at 3. A reasonable target operating point is DTM yield=99.4% and wafer die yield=99.6%.

In another aspect, in an embodiment, a two-operation process for transferring micro LEDs from silicon wafer to display backplane is disclosed, such as described in association with FIGS. 13A and 13B. First, selective bonding is performed using thermo-compression bonding (TCB). Next, selective release of micro LEDs is performed using backside (silicon side) irradiation with infra-red laser with wavelength >1300 nm. In another embodiment, a blanket release and selective bond approach is described as a two-operation process for transferring micro LEDs from a silicon wafer to a display backplane. First, blanket release of all micro LEDs is performed using “front-side” irradiation with infra-red laser with wavelength >1000 nm. Next, selective bonding of micro LEDs is performed using TCB, followed by mechanical removal of micro LEDs. from the silicon wafer.

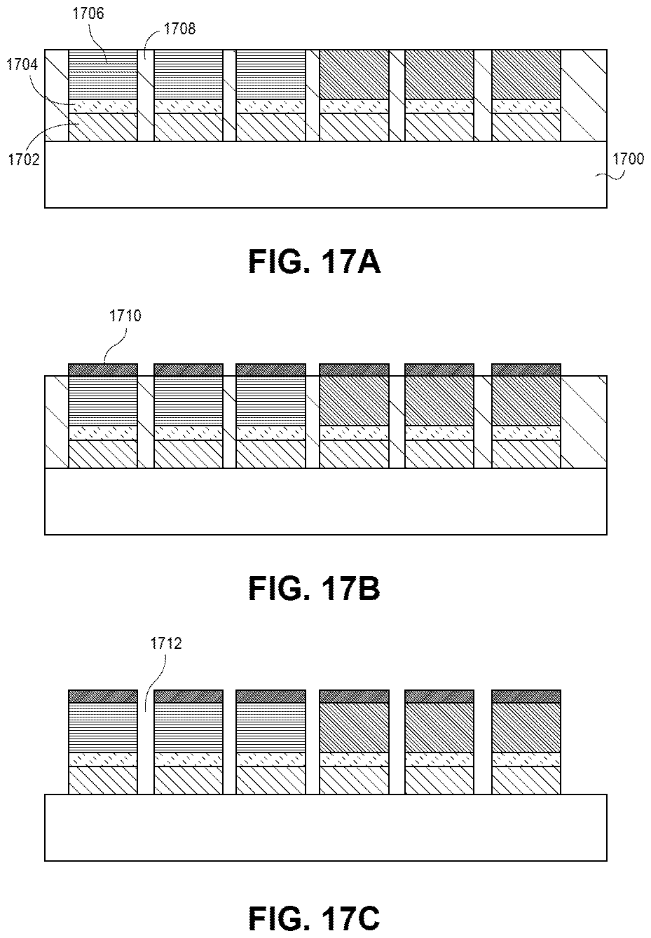

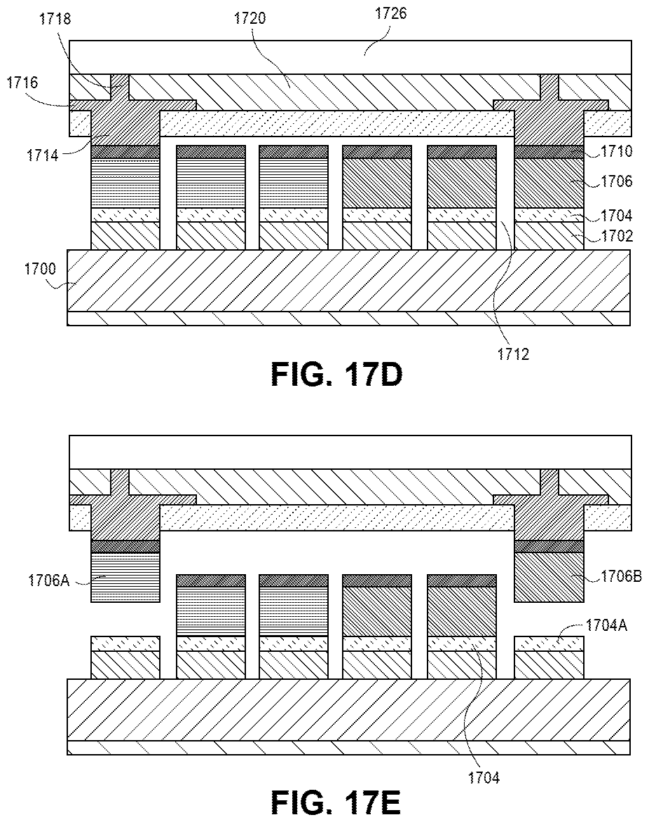

As an example of a blanket release approach, FIGS. 17A-17E illustrate cross-sectional views of various operations in a method of assembling a micro LED display, in accordance with an embodiment of the present disclosure.

Referring to FIG. 17A, an LED substrate 1700, such as a silicon wafer, has a patterned growth or nucleation layer 1702 thereon, such as a patterned aluminum nitride layer. Individual micro LEDs 1706 are associated with each pattern feature of the patterned growth or nucleation layer 1702. A release layer 1704, such as a metal nitride layer, may be between the individual micro LEDs 1706 and the associated pattern feature of the patterned growth or nucleation layer 1702, as is depicted. An insulating layer 1708 surrounds the micro LEDs 1706.

In an embodiment, “blanket release” of micro LEDs is performed by irradiation (e.g., through the wide-bandgap micro LEDs) with infra-red laser with a wavelength >1000 nm. The release layer (transition metal nitride) absorbs the infra-red radiation and bonds between the release layer and micro LEDs become very weak.

Referring to FIG. 17B, a metal bonding layer 1710, such as a copper or aluminum layer, is formed as a pad on each of the individual micro LEDs 1706. The insulating layer 1708 is then removed, as depicted in FIG. 17C.

Referring to FIG. 17D, a backplane 1726 is positioned opposite the substrate 1700. The backplane 1726 includes a dielectric layer 1720 having conductive features therein. The conductive features may include reflective plates 1716 and associated vias 1718. Metal pads or bumps 1714 are on the reflective plates 1716. Mechanical separation of the micro LEDs from silicon wafer is then performed, as is depicted in FIG. 17E. Referring to FIG. 17E, release occurs at location labeled 1704A, 1706A and 1706B.

It is to be appreciated that, as contemplated for embodiments described herein, typically, a plurality of micro LEDs with different colors that have been grown on a single wafer monolithically is ultimately transferred to the display backplane. The scope is thus not limited to transferring “RGB chips”. It is also to be appreciated that the above bonding approaches may be performed in a bonder too such as tool 200 described above in association with FIG. 2.

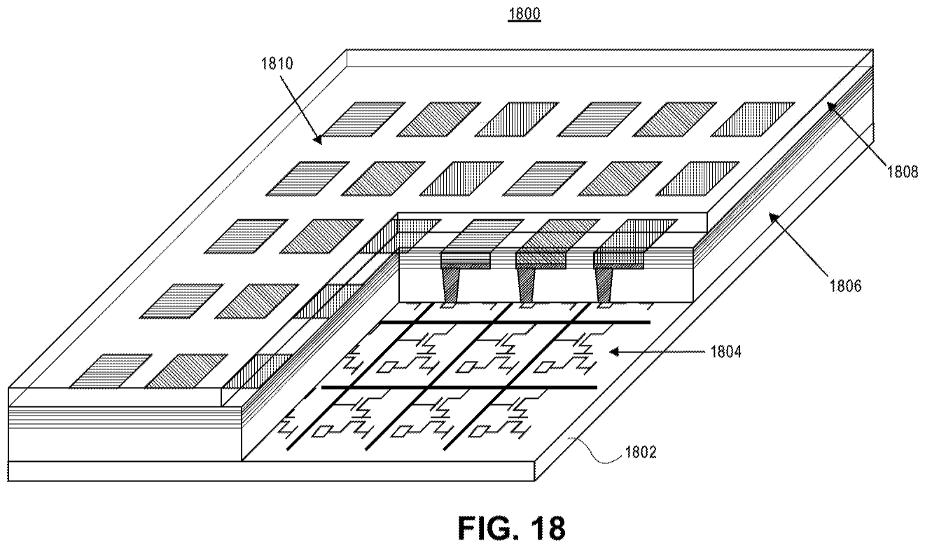

As an exemplary display architecture, FIG. 18 illustrates a schematic of micro LED display architecture, in accordance with an embodiment of the present disclosure. Referring to FIG. 18, a micro LED display 1800 includes a backplane 1802 having pixel circuits 1804 thereon. An insulator 1806 is over the pixel circuits 1804. Micro LED layers 1808 are included over the insulator 1806. A transparent electrode 1810 is over the micro LED layers 1808.

It is to be appreciated that, in contrast to one or more embodiments described herein, state of the art approaches involve fabricating discrete red, green, and blue μLEDs on separate wafers and then transferring the μLEDs using pick and place assembly to the display backplane. Such state of the art solutions are associated with high manufacturing cost due to the slow transfer rate of three types of μLEDs sequentially from source wafers to backplane. In addition, since three sequential transfers are needed, the probability of missing transfers increases and can result in low yield. This may be particularly impactful for displays used in smartphones (e.g., diagonal=5.1 inches), converged mobility tablets (e.g., diagonal=7 inches), and mobile notebooks (e.g., diagonal=11.6 inches-13.3 inches).

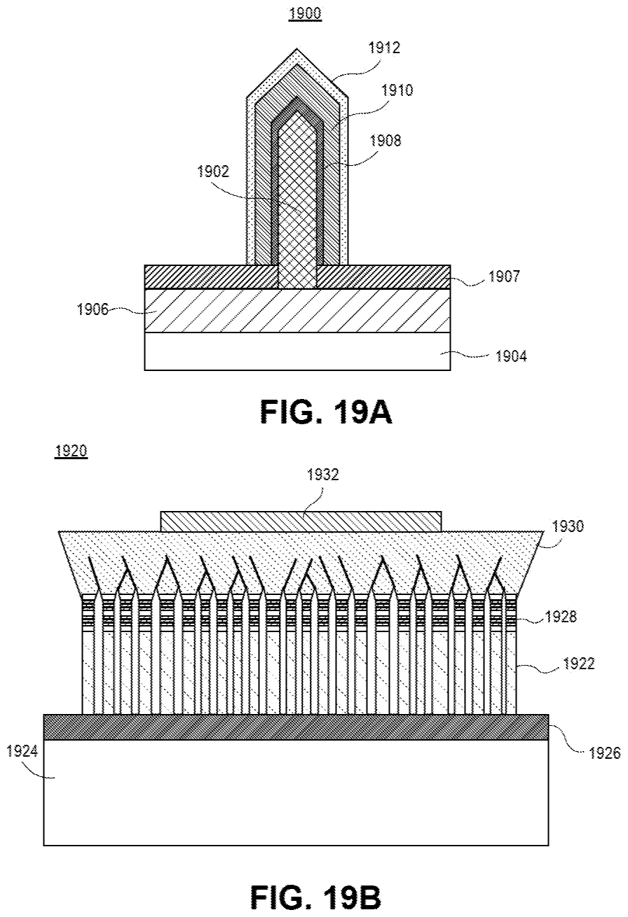

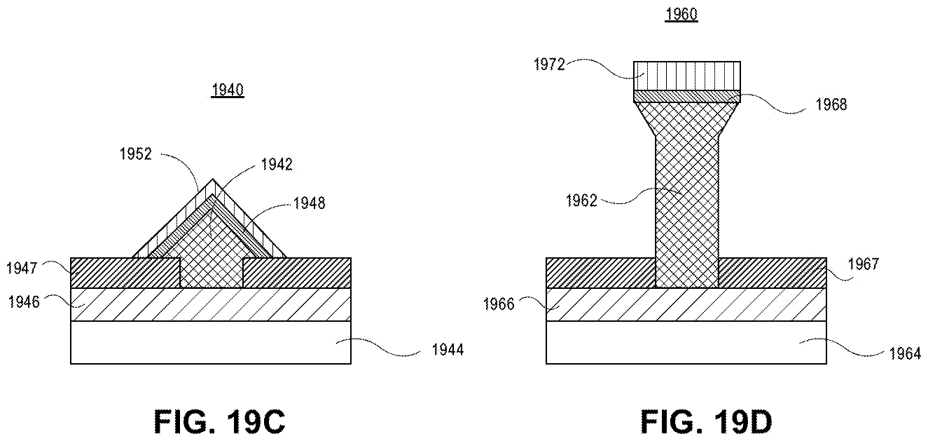

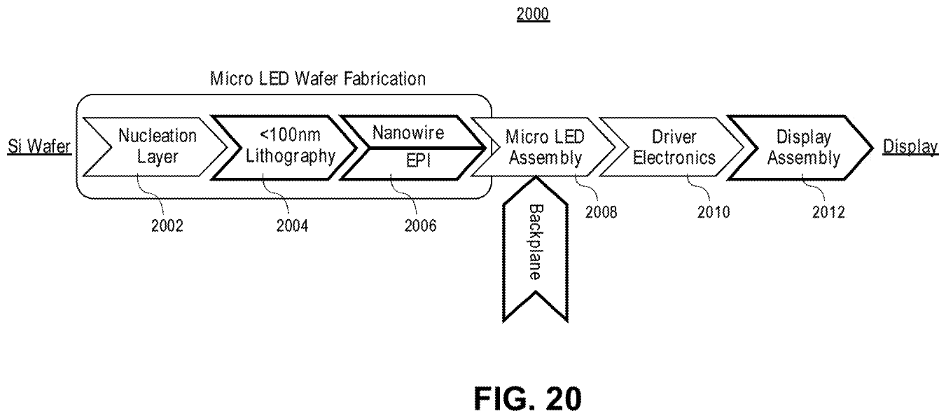

In another aspect, micro LEDs can be co-axial (core-shell) nanowire, nanopyramids, or axial nanowire, examples of which are described below in association with FIGS. 19A-19D. An exemplary fabrication scheme is described below in association with FIG. 20.

FIGS. 19A-19D illustrate options for micro LED structures. In a first example, FIG. 19A illustrates a cross-sectional view of a GaInP or GaN nanowire based LED highlighting certain layers of the LED, in accordance with an embodiment of the present disclosure. In a particular embodiment, an LED 1900 includes, in the case of a blue or green LED, an n-type GaN nanowire 1902 or, in the case of a red LED, an n-type GaInP nanowire 1902. The GaInP nanowire 1902 or GaN nanowire 1902 is above a substrate 1904, which may be a Si(111) substrate. An intervening nucleation layer 1906 has an opened mask layer 1907 thereon. In one embodiment, the n-type GaInP nanowire 1902 or the n-type GaN nanowire 1902 has a diameter in the range of 100-200 nanometers, and a height in the range of 1-10 microns.

In one embodiment, in the case of a blue or green LED, the n-type GaN nanowire 1902 is formed on a MN/AlN nucleation layer 1906 layer with MN=metal nitride, and where the metal can be Ti, Hf, Nb, etc. An active layer 1908 of InGaN is on the n-type GaN nanowire 1902. A p-GaN cladding layer 1910 is included on the active layer 1908. A conductive electrode layer 1912 may be formed on the p-GaN cladding layer 1910, as is depicted. In another embodiment, in the case of a red LED, the n-type GaInP nanowire 1902 is formed on a GaAs nucleation layer 1906. An active layer 1908 of AlInGaP is on the n-type GaInP nanowire 1902. A p-GaInP cladding layer 1910 is included on the active layer 1908. A conductive electrode layer 1912 may be formed on the p-GaInP cladding layer 1910, as is depicted. In one such embodiment, the AlInGaP 1908 emits red color (e.g., having a wavelength in the range of 610-630 nanometers).

In a second example, FIG. 19B illustrates a cross-sectional view of a micro-LED composed of multiple nanowire LEDs, in accordance with an embodiment of the present disclosure. In the exemplary embodiment of FIG. 19B, a micro-LED 1920 includes an n-GaN nano-column 1922 above a substrate 1924, which may be an n-type Si(111) substrate. An intervening nucleation layer 1926, such as an AlN layer, is included between the n-GaN nano-column 1922 and the substrate 1924 or, alternatively, the nucleation layer 1926 may be omitted. An InGaN/GaN multi-quantum well device (MQD) stack 1928 is included on the n-GaN nano-column 1922. A p-GaN layer 1930 is on the multi-quantum well device (MQD) stack 1928. A transparent p-electrode 1932 is included on the p-GaN layer 1930.

It is to be appreciated that foundational geometries other than the above described nanowires may be used for LED fabrication. In a third example, in another embodiment, FIG. 19C illustrates a cross-sectional view of a nanopyramid or micropyramid based LED highlighting certain layers of the LED, in accordance with an embodiment of the present disclosure. In a particular embodiment, an LED 1940 includes an n-GaN (in the case of a blue or green LED) or n-GaInP (in the case of a red LED) nanopyramid 1942 above a substrate 1944, which may be a Si(111) substrate. An intervening nucleation layer 1946, such as described for FIG. 19A, has an opened mask layer 1947 thereon. An active layer 1948, such as described for FIG. 19A, is included on the n-GaN or n-GaInP nanopyramid 1942. A p-type cladding layer 1952, such as described for FIG. 19A, is included on the active layer 1948. It is to be appreciated that a micro LED may be composed of multiple nanopyramids connected in parallel. For example, a 5 micron×5 micron micro LED may be composed of, e.g., 20 nanopyramids.

In a fourth embodiment, FIG. 19D illustrates a cross-sectional view of an axial nanowire based LED highlighting certain layers of the LED, in accordance with an embodiment of the present disclosure. In a particular embodiment, an LED 1960 includes an n-GaN or n-GaInP axial nanowire 1962 above a substrate 1964, which may be a Si(111) substrate. An intervening active layer 1966, such as described for FIG. 19A, has an opened mask layer 1967 thereon. An active layer 1968, such as described for FIG. 19A, is included on the n-GaN or n-GaInP axial nanowire 1962. A p-type cladding layer 1972, such as described for FIG. 19A, is included on the active layer 1968.

It is to be appreciated that hybrid structures may also be fabricated. In one such embodiment, green and blue LEDs are nanowires (core-shell or axial nanowires) and the red LED is a nanopyramid or micro pyramid. Other combinations include the green and blue LEDs being based on nanopyramids or micro pyramids while the red LED is based on nanopyramids or nanowires, etc.

In another aspect, FIG. 20 is a flow diagram 2000 illustrating an RGB display production process, in accordance with an embodiment of the present disclosure. Referring to flow diagram 2000, at operation 2002, a Si wafer has a nucleation layer formed thereon, such as an AlN nucleation layer, and metal nitride/AlN nucleation layer or a GaAs nucleation layer. At operation 2004, sub 100 nanometer lithography is used to pattern a layer on the nucleation layer, or to pattern the nucleation layer. At operation 2006, nanowire growth is performed on the nucleation layer, e.g., by epitaxial deposition. At operation 2008, a backplane is introduced into the micro LED assembly process. At operation 2010, driver electrons are fabricated. At operation 2012, display assembly is performed to finally provide a display.

Advantages of implementing one or more embodiments described herein may include, but need not be limited to (1) low manufacturing cost (e.g., accomplished by transferring red-green-blue micro LED pixels in one pass from a silicon wafer to a display backplane resulting in faster transfer rate and higher yield (e.g., lower transfer-related defects on the display), (2) low power consumption (e.g., accomplished by realizing high efficiency red, green and blue micro LEDs at the same time), and/or (3) a projected power reduction of approximately 3-5× compared to OLED technology. In an embodiment, power reduction is achieved with micro LED displays based on the fabrication of LEDs with high power efficacies for all three color LED emitters.

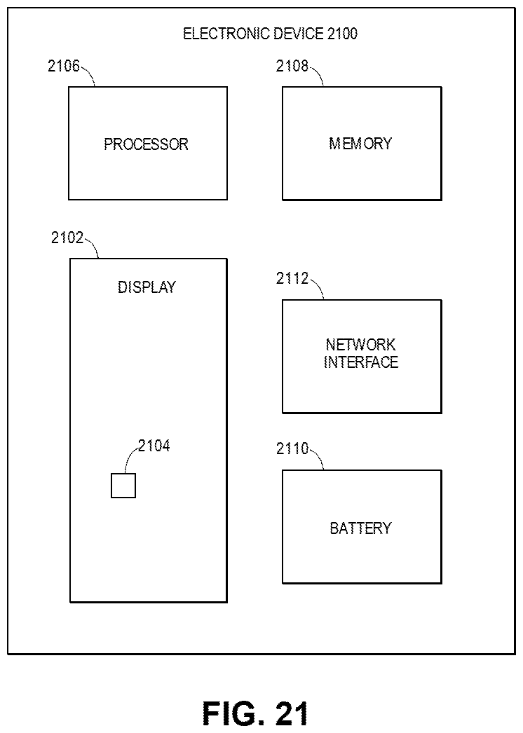

FIG. 21 is an electronic device having a display, in accordance with embodiments of the present disclosure. Referring to FIG. 21, an electronic device 2100 has a display or display panel 2102 with a micro-structure 2104. The display may also have glass layers and other layers, circuitry, and so forth. The display panel 2102 may be a micro-LED display panel. As should be apparent, only one microstructure 2104 is depicted for clarity, though a display panel 2102 will have an array or arrays of microstructures including nanowire LEDs.

The electronic device 2100 may be a mobile device such as smartphone, tablet, notebook, smartwatch, and so forth. The electronic device 2100 may be a computing device, stand-alone display, television, display monitor, vehicle computer display, the like. Indeed, the electronic device 2100 may generally be any electronic device having a display or display panel.

The electronic device 2100 may include a processor 2106 (e.g., a central processing unit or CPU) and memory 2108. The memory 2108 may include volatile memory and nonvolatile memory. The processor 2106 or other controller, along with executable code store in the memory 2108, may provide for touchscreen control of the display and well as for other features and actions of the electronic device 2100.

In addition, the electronic device 2100 may include a battery 2110 that powers the electronic device including the display panel 2102. The device 2100 may also include a network interface 2112 to provide for wired or wireless coupling of the electronic to a network or the internet. Wireless protocols may include Wi-Fi (e.g., via an access point or AP), Wireless Direct®, Bluetooth®, and the like. Lastly, as is apparent, the electronic device 2100 may include additional components including circuitry and other components.

Thus, embodiments described herein include micro light-emitting diode display fabrication processes and assembly apparatuses.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

### Example Embodiment 1

A micro light emitting diode pixel structure includes a backplane including a glass substrate having an insulating layer disposed thereon, and a pixel thin film transistor circuit disposed in and on the insulating layer, the pixel thin film transistor circuit including a gate electrode and a channel. The micro light emitting diode pixel structure also includes a front plane including a metal pad coupled to the pixel thin film transistor circuit of the backplane, a micro light emitting diode device bonded to the metal pad, a spacer adjacent sidewalls of the micro light emitting diode, the spacer including a high refractive index material, and an insulating layer surrounding the spacer.

### Example Embodiment 2

The micro light emitting diode pixel structure of example embodiment 1, wherein the high refractive index material of the spacer includes titanium oxide or silicon nitride.

### Example Embodiment 3

The micro light emitting diode pixel structure of example embodiment 1 or 2, further including a second spacer between the spacer and the insulating layer, the second spacer including a second high refractive index material.

### Example Embodiment 4

The micro light emitting diode pixel structure of example embodiment 3, wherein the high refractive index material of the spacer includes titanium oxide or silicon nitride, and wherein the second high refractive index material of the second spacer includes titanium oxide or silicon nitride.

### Example Embodiment 5

The micro light emitting diode pixel structure of example embodiment 1, 2, 3 or 4, wherein the metal pad is coupled to the pixel thin film transistor circuit of by a reflective plate or mirror.

### Example Embodiment 6

The micro light emitting diode pixel structure of example embodiment 1, 2, 3, 4 or 5, further including a transparent conducting oxide layer disposed above the insulating layer.

### Example Embodiment 7

The micro light emitting diode pixel structure of example embodiment 1, 2, 3, 4, 5 or 6, wherein the channel of the pixel thin film transistor circuit includes a semiconducting oxide material.

### Example Embodiment 8

The micro light emitting diode pixel structure of example embodiment 7, wherein the semiconducting oxide material is indium gallium zinc oxide (IGZO).

### Example Embodiment 9

The micro light emitting diode pixel structure of example embodiment 1, 2, 3, 4, 5 or 6, wherein the channel of the pixel thin film transistor circuit includes a low temperature polysilicon material.

### Example Embodiment 10

The micro light emitting diode pixel structure of example embodiment 1, 2, 3, 4, 5, 6, 7, 8 or 9, wherein the micro light emitting diode device is a nanowire-based micro light emitting diode device.

### Example Embodiment 11

A method of manufacturing a micro-light emitting diode (LED) display panel includes positioning a silicon substrate above a display backplane substrate, the silicon substrate having a plurality of light-emitting diode (LED) pixel elements thereon, and the display backplane substrate having a plurality of metal bumps thereon. The method also includes joining the display backplane substrate and the silicon substrate to couple only a portion of the plurality of LED pixel elements to corresponding ones of the plurality of metal bumps. The method also includes irradiating only the portion of the plurality of LED pixel elements with an infra-red (IR) laser source to transfer only the portion of the plurality of LED pixel elements to the corresponding ones of the plurality of metal bumps. The method also includes, subsequently, separating the silicon substrate from the display backplane substrate.

### Example Embodiment 12

The method of example embodiment 11, wherein irradiating only the portion of the plurality of LED pixel elements with the IR laser source includes irradiating with an IR beam having a spot size approximately the same size as an individual one of the plurality of LED pixel elements.

### Example Embodiment 13

The method of example embodiment 12, wherein the spot size is approximately 5 microns.

### Example Embodiment 14

The method of example embodiment 11, 12 or 13, wherein the IR laser source includes a rotating meta-surface.

### Example Embodiment 15

The method of example embodiment 11, 12, 13 or 14, wherein irradiating only the portion of the plurality of LED pixel elements with the IR laser source includes performing a sweep of a laser angle by shifting a surface including arrays of anomalous refractive or reflective meta-surfaces.

### Example Embodiment 16

The method of example embodiment 15, wherein each array of meta-surfaces has a pre-determined angle through which incident light is refracted or reflected.

### Example Embodiment 17

The method of example embodiment 11, 12, 13, 14, 15 or 16, wherein the plurality of LED pixel elements is grown on the silicon substrate.

### Example Embodiment 18

The method of example embodiment 11, 12, 13, 14, 15, 16 or 17, wherein the plurality of LED pixel elements is a plurality of nanowire-based LED pixel elements.

### Example Embodiment 19

The method of example embodiment 18, wherein the plurality of nanowire-based LED pixel elements includes GaN nanowires.

### Example Embodiment 20

A display bonder apparatus includes a first support for holding a display backplane substrate in a first position. A second support is for holding a silicon substrate in a second position, the second position over the first position. A mechanism is to align the display backplane substrate to the silicon substrate. A piston is coupled to the second support, the piston for moving the silicon substrate from the second position toward the first position, and the piston for applying a force to the silicon substrate to bond light-emitting diode (LED) pixel elements from the silicon substrate to metal bumps on the display backplane substrate. An infra-red (IR) laser source is to irradiate only the portion of the plurality of LED pixel elements to transfer only the portion of the plurality of LED pixel elements to the corresponding ones of the plurality of metal bumps, where the IR laser source includes a rotating meta-surface.

### Example Embodiment 21

The display bonder apparatus of example embodiment 20, wherein the IR laser source is to provide an IR beam having a spot size approximately the same size as an individual one of the plurality of LED pixel elements.

### Example Embodiment 22

The display bonder apparatus of example embodiment 21, wherein the spot size is approximately 5 microns.

### Example Embodiment 23

The display bonder apparatus of example embodiment 20, 21 or 22, wherein the IR laser source is to perform a sweep of a laser angle by shifting a surface including arrays of anomalous refractive or reflective meta-surfaces of the rotating meta-surface.

### Example Embodiment 24

The display bonder apparatus of example embodiment 23, wherein each array of meta-surfaces has a pre-determined angle through which incident light is refracted or reflected.

### Example Embodiment 25

The display bonder apparatus of example embodiment 20, 21, 22, 23 or 24, wherein the piston is further to separate the silicon substrate from the display backplane substrate after transferring only the portion of the plurality of LED pixel elements to the corresponding ones of the plurality of metal bumps.

What is claimed is:

1. A micro light emitting diode pixel structure, comprising:
a backplane, comprising:
a glass substrate having an insulating layer disposed thereon; and
a pixel thin film transistor circuit disposed in and on the insulating layer, the pixel thin film transistor circuit comprising a gate electrode and a channel; and
a front plane, comprising:
a metal pad coupled to the pixel thin film transistor circuit of the backplane;
a micro light emitting diode device bonded to the metal pad;
a spacer adjacent sidewalls of the micro light emitting diode, the spacer comprising a high refractive index material; and
an insulating layer surrounding the spacer.

2. The micro light emitting diode pixel structure of claim 1, wherein the high refractive index material of the spacer comprises titanium oxide or silicon nitride.

3. The micro light emitting diode pixel structure of claim 1, further comprising a second spacer between the spacer and the insulating layer, the second spacer comprising a second high refractive index material.

4. The micro light emitting diode pixel structure of claim 3, wherein the high refractive index material of the spacer comprises titanium oxide or silicon nitride, and wherein the second high refractive index material of the second spacer comprises titanium oxide or silicon nitride.

5. The micro light emitting diode pixel structure of claim 1, wherein the metal pad is coupled to the pixel thin film transistor circuit of by a reflective plate or mirror.

6. The micro light emitting diode pixel structure of claim 1, further comprising a transparent conducting oxide layer disposed above the insulating layer.

7. The micro light emitting diode pixel structure of claim 1, wherein the channel of the pixel thin film transistor circuit comprises a semiconducting oxide material.

8. The micro light emitting diode pixel structure of claim 7, wherein the semiconducting oxide material is indium gallium zinc oxide (IGZO).

9. The micro light emitting diode pixel structure of claim 1, wherein the channel of the pixel thin film transistor circuit comprises a low temperature polysilicon material.

10. The micro light emitting diode pixel structure of claim 1, wherein the micro light emitting diode device is a nanowire-based micro light emitting diode device.

11. A method of manufacturing a micro-light emitting diode (LED) display panel, the method comprising:
positioning a silicon substrate above a display backplane substrate, the silicon substrate having a plurality of light-emitting diode (LED) pixel elements thereon, and the display backplane substrate having a plurality of metal bumps thereon;
joining the display backplane substrate and the silicon substrate to couple only a portion of the plurality of LED pixel elements to corresponding ones of the plurality of metal bumps;
irradiating only the portion of the plurality of LED pixel elements with an infra-red (IR) laser source to transfer only the portion of the plurality of LED pixel elements to the corresponding ones of the plurality of metal bumps; and, subsequently,
separating the silicon substrate from the display backplane substrate.

12. The method of claim 11, wherein irradiating only the portion of the plurality of LED pixel elements with the IR laser source comprises irradiating with an IR beam having a spot size approximately the same size as an individual one of the plurality of LED pixel elements.

13. The method of claim 12, wherein the spot size is approximately 5 microns.

14. The method of claim 11, wherein the IR laser source comprises a rotating meta-surface.

15. The method of claim 11, wherein irradiating only the portion of the plurality of LED pixel elements with the IR laser source comprises performing a sweep of a laser angle by shifting a surface comprising arrays of anomalous refractive or reflective meta-surfaces.

16. The method of claim 15, wherein each array of meta-surfaces has a pre-determined angle through which incident light is refracted or reflected.

17. The method of claim 11, wherein the plurality of LED pixel elements is grown on the silicon substrate.

18. The method of claim 11, wherein the plurality of LED pixel elements is a plurality of nanowire-based LED pixel elements.

19. The method of claim 18, wherein the plurality of nanowire-based LED pixel elements comprises GaN nanowires.

20. A display bonder apparatus, comprising:
a first support for holding a display backplane substrate in a first position;
a second support for holding a silicon substrate in a second position, the second position over the first position;
a mechanism to align the display backplane substrate to the silicon substrate;
a piston coupled to the second support, the piston for moving the silicon substrate from the second position toward the first position, and the piston for applying a force to the silicon substrate to bond light-emitting diode (LED) pixel elements from the silicon substrate to metal bumps on the display backplane substrate; and
an infra-red (IR) laser source to irradiate only the portion of the plurality of LED pixel elements to transfer only the portion of the plurality of LED pixel elements to the corresponding ones of the plurality of metal bumps, wherein the IR laser source comprises a rotating meta-surface.

21. The display bonder apparatus of claim 20, wherein the IR laser source is to provide an IR beam having a spot size approximately the same size as an individual one of the plurality of LED pixel elements.

22. The display bonder apparatus of claim 21, wherein the spot size is approximately 5 microns.

23. The display bonder apparatus of claim 20, wherein the IR laser source is to perform a sweep of a laser angle by shifting a surface comprising arrays of anomalous refractive or reflective meta-surfaces of the rotating meta-surface.

24. The display bonder apparatus of claim 23, wherein each array of meta-surfaces has a pre-determined angle through which incident light is refracted or reflected.

25. The display bonder apparatus of claim 20, wherein the piston is further to separate the silicon substrate from the display backplane substrate after transferring only the portion of the plurality of LED pixel elements to the corresponding ones of the plurality of metal bumps.
